(19) United States
(12) Patent Application Publication
(10) Pub. No.: US 2026/0362749 A1
(43) Pub. Date: Nov. 12, 2026

(54) SEMICONDUCTOR TRANSISTOR AND METHOD OF MANUFACTURING THE SAME

(71) Applicant: National Sun Yat-sen University, Kaohsiung City (TW)

(72) Inventors: Hsin-chu CHEN, Kaohsiung City (TW); Chi-yuan KUO, Kaohsiung City (TW); Chih-i WU, Kaohsiung City (TW)

(73) Assignee: National Sun Yat-sen University, Kaohsiung City (TW)

(21) Appl. No.: 19/668,847

(22) Filed: May 6, 2026

(30) Foreign Application Priority Data
May 9, 2025 (TW) 114117621

(51) Int. Cl. H10D 30/67; H10D 30/01; H10P 14/20; H10P 14/22; H10W 74/10; H10W 74/43

(52) U.S. Cl. CPC H10D 30/6755; H10D 30/0316; H10D 30/6706; H10D 30/6732; H10D 30/6736; H10D 30/6757; H10P 14/22; H10P 14/3434; H10W 74/137; H10W 74/43

(57) ABSTRACT

A semiconductor transistor and a method of manufacturing the same are provided. The semiconductor transistor includes a substrate having a gate electrode and a dielectric layer; a laminated copper oxide layer disposed on the substrate; a passivation layer covering the laminated copper oxide layer; and a source/drain layer disposed on the passivation layer and electrically connected to the laminated copper oxide layer. The laminated copper oxide layer includes at least one Cu₂O layer and at least one CuOₓ layer, in which x is greater than or equal to 1. The at least one Cu₂O layer and the at least one CuOₓ layer are stacked with each other. The method of manufacturing the semiconductor transistor includes steps of using a plasma system to form the laminated copper oxide layer and annealing at a temperature ranging from 300 to 350 °C.

### CROSS REFERENCE TO RELATED APPLICATIONS

This application claims the priority of Taiwan Patent Application Serial No. 114117621, filed on May 9, 2025, the disclosure of which is incorporated herein by reference.

### FIELD OF INVENTION

The present invention relates to a semiconductor transistor and a method of manufacturing the same, in particular to a semiconductor transistor having a laminated copper oxide layer and a method of manufacturing the same.

### BACKGROUND OF INVENTION

In conventional processes for fabricating thin-film transistors, copper oxide films are generally prepared by wet chemical methods by using copper nitrate and ligands. However, these methods are easily influenced by processing conditions, leading to residual by-products and difficulties in controlling oxygen vacancies. As a result, the prepared films exhibit surface roughness and crystalline defects, which are detrimental to the stability and performance of the devices in electrical properties.

Moreover, thin-film transistors containing Cu₂O or CuOₓ are generally not comprehensively evaluated for the incorporation of a passivation layer, or lack methods to achieve a high-quality passivation layer. Free copper ions on the surface tend to induce charge accumulation and a high off-state current, thereby impairing leakage suppression and operational stability of semiconductor devices.

It is therefore necessary to provide a semiconductor transistor and a method of manufacturing the semiconductor transistor, in order to solve the problems existing in the conventional technology as described above.

### SUMMARY OF DISCLOSURE

A primary object of the present invention is to provide a semiconductor transistor and a method of manufacturing the same. The present invention provides a semiconductor transistor comprising a laminated copper oxide film which can reduce the oxygen vacancies in existing transistors, thereby improving an excessively low current on/off ratio in p-type oxide TFTs. Furthermore, the method of manufacturing the semiconductor transistor does not use doping technology, the method only utilizes ionized gas to perform an oxidation treatment on a cuprous oxide (Cu₂O) film to generate a copper oxide layer (represented as CuOₓ) on a surface of the cuprous oxide film. This results in a more uniform laminated copper oxide film and improves the quality of the copper oxide film. After electrical testing, the current on/off ratio (Iₒₙ/I_{off}) is improved by up to 1.4×10².

To achieve the above objects, one embodiment of the present invention provides a semiconductor transistor, comprising a substrate comprising a gate electrode and a dielectric layer, wherein the dielectric layer is disposed on the gate electrode; a laminated copper oxide layer disposed on the substrate; a passivation layer covering the laminated copper oxide layer, wherein the passivation layer has a source opening and a drain opening; and a source/drain layer disposed on the passivation layer, wherein the source/drain layer comprises a source electrode and a drain electrode, and wherein the source electrode and the drain electrode electrically connect the laminated copper oxide layer through the source opening and the drain opening, respectively; wherein the laminated copper oxide layer comprises at least one Cu₂O layer and at least one CuOₓ layer, one of the at least one Cu₂O layer and one of the at least one CuOₓ layer are stacked with each other, and x is greater than or equal to 1.

In one embodiment of the present invention, the dielectric layer comprises silicon dioxide (SiO₂).

In one embodiment of the present invention, the passivation layer comprises aluminum oxide (Al₂O₃).

In one embodiment of the present invention, the laminated copper oxide layer has a thickness ranging from 9.6 nm to 14.4 nm.

In one embodiment of the present invention, the semiconductor transistor has a leakage current less than 10 pA/μm.

To achieve the above objectives, another embodiment of the present invention provides a method of manufacturing a semiconductor transistor, comprising steps of:
(S1) providing a substrate comprising a gate electrode and a dielectric layer disposed on the gate electrode;
(S2) sputtering a cuprous oxide (Cu₂O) layer on the substrate by using a plasma system;
(S3) performing an oxidation treatment to form a CuOₓ layer on a surface of the Cu₂O layer, wherein x is greater than or equal to 1;
(S4) repeating the step (S2) and the step (S3) to obtain a laminated copper oxide layer;
(S5) providing a passivation layer on the laminated copper oxide layer, wherein the passivation layer has a source opening and a drain opening; and
(S6) providing a source/drain layer on the passivation layer, wherein the source/drain layer comprises a source electrode and a drain electrode, the source electrode and the drain electrode electrically connect the laminated copper oxide layer through the source opening and the drain opening, respectively.

In one embodiment of the present invention, in the step (S1), the dielectric layer comprises silicon dioxide, and the dielectric layer has a thickness ranging from 20 nm to 150 nm.

In one embodiment of the present invention, in the step (S2), the plasma system provides an oxygen plasma flow for sputtering, and in the step (S3), the oxidation treatment is performed in the plasma system when the oxygen plasma flow is stopped from being injected into the plasma system.

In one embodiment of the present invention, the oxidation treatment is performed at a temperature of 20-30 °C for 9.5-10.5 minutes.

In one embodiment of the present invention, the laminated copper oxide layer has a thickness ranging from 9.6 nm to 14.4 nm.

In one embodiment of the present invention, in the step (S4), the number of times of repeating the step (S2) is different from or the same as the number of times of repeating the step (S3).

In one embodiment of the present invention, further comprising a step after the step (S5):(S51) annealing in a vacuum at a temperature of 300 °C-350 °C for 10-15 minutes.

### BRIEF DESCRIPTION OF DRAWINGS

FIG. 1 is a structural schematic view of a semiconductor transistor according to one embodiment of the present invention.

FIG. 2 is a flow chart showing a method of manufacturing a semiconductor transistor according to one embodiment of the present invention.

FIGS. 3A-3D are longitudinal cross-section views of a semiconductor transistor in a method of manufacturing a semiconductor transistor according to one embodiment of the present invention.

### DETAILED DESCRIPTION OF PREFERRED EMBODIMENTS

The structure and the technical means adopted by the present invention to achieve the above and other objects can be best understood by referring to the following detailed description of the preferred embodiments. Furthermore, if there is no specific description in the invention, singular terms such as “a”, “one”, and “the” include the plural number. For example, “a compound” or “at least one compound” may include a plurality of compounds, and the mixtures thereof. If there is no specific description in the invention, “%” means “weight percentage (wt %)”, and the numerical range (e.g., 10% to 11% of A) contains the upper and lower limit (i.e., 10%≤A≤11%). If the lower limit is not defined in the range (e.g., less than, or below 0.2% of B), it means that the lower limit may be 0 (i.e., 0%≤B≤0.2%). The proportion of “weight percent” of each component can be replaced by the proportion of “weight portion” thereof. Furthermore, directional terms described by the present invention, such as upper, lower, front, back, left, right, inner, outer, side, etc., are only directions by referring to the accompanying drawings, and thus the directional terms are used to describe and understand the present invention. The abovementioned terms are used to describe and understand the present invention, but the present invention is not limited thereto.

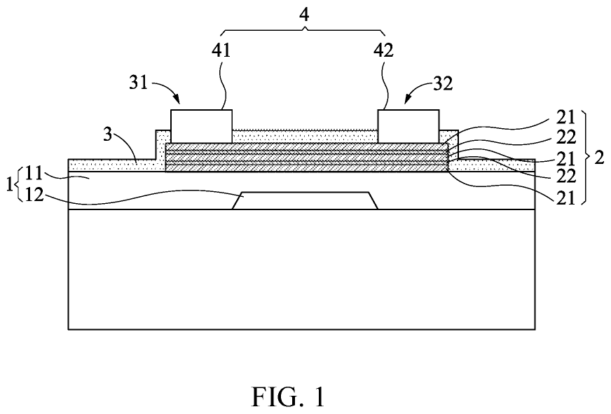

Referring to FIG. 1, a structural schematic view of a semiconductor transistor according to one embodiment of the present invention is shown. The semiconductor transistor mainly comprises a substrate 1, a laminated copper oxide layer 2, a passivation layer 3, and a source/drain layer 4.

In one embodiment, the substrate 1 comprises a dielectric layer 11 and a gate electrode 12. The dielectric layer 11 is disposed on the gate electrode 12. The substrate 1 may be made of any material used for manufacturing a transistor. The material of the substrate 1 may be selected based on the implementation requirements. For example, the material of the substrate 1 may be silicon wafers, P++ silicon wafers, n++ silicon wafers, or metals. In mass production, the substrate 1 may also comprise a gate electrode array formed by a plurality of gate electrodes 12.

In one embodiment, the laminated copper oxide layer 2 is disposed on the substrate 1. Preferably, the dielectric layer 11 is disposed between the laminated copper oxide layer 2 and the gate electrode 12. The dielectric layer 11 may comprise silicon dioxide, aluminum oxide, Al₂O₃, silicon nitride, hafnium dioxide, aluminum nitride, titanium oxide, nickel oxide, and/or hexagonal boron nitride. The dielectric layer 11 may have a thickness ranging from 20 nm to 150 nm, such as 20 nm, 50 nm, 80 nm, 100 nm, 150 nm, but is not limited thereto. The dielectric layer may have a thickness of any integer or non-integer value in the range of 20-150 nanometers. Preferably, the laminated copper oxide layer 2 mainly comprises at least one cuprous oxide (Cu₂O) layer and at least one copper oxide (CuOₓ with x greater than or equal to 1) layer and they are stacked with each other. Preferably, the at least one Cu₂O layer 21 and the at least one CuOₓ layer 22 form a sandwich structure. The sandwich structure is that one CuOₓ layer 22 is disposed between one Cu₂O layer 21 and another one Cu₂O layer 21. Alternatively, one Cu₂O layer 21 may be disposed between one CuOₓ layer 22 and another one CuOₓ layer 22. Preferably, one of the at least one Cu₂O layer 21 directly contacts the dielectric layer 11. Preferably, one Cu₂O layer 21 is disposed on or below the at least one CuOₓ layer 22. Alternatively, each Cu₂O layer 21 may have a thickness the same as or different from each other. Alternatively, each CuOₓ layer 22 may have a thickness the same as or different from each other. Alternatively, the laminated copper oxide layer 2 may have one Cu₂O layer 21 with a thickness the same as or different from a thickness of one CuOₓ layer 22. Preferably, a top layer above the laminated copper oxide layer 2 is one Cu₂O layer 21. Preferably, the laminated copper oxide layer 2 has a thickness of 12 nm±20%, such as 9.6-14.4 nm, 9.6 nm, 10 nm, 11.2 nm, 12 nm, 13 nm, or 14 nm, but is not limited thereto. It can also be any thickness between 9.6 and 14.4 nm. Preferably, one Cu₂O layer 21 and one CuOₓ layer 22 form a total thickness of 3-4 nm, such as 3, 3.2, 3.5, 3.8, or 4 nm.

In one embodiment, the passivation layer 3 covers the laminated copper oxide layer 2. The passivation layer 3 may have at least one source opening 31 and at least one drain opening 32. In one embodiment, the passivation layer 3 further covers the substrate 1. In one embodiment, the source opening 31 and the drain opening 32 may be formed by using any conventional means. Preferably, the source opening 31 and the drain opening 32 may be formed by etching, but they are not limited thereto. The passivation layer 3 may be made of any material of a passivation layer known in the art, such as aluminum oxide (Al₂O₃), silicon dioxide (SiO₂), AIO, silicon nitride (Si₃N₄), hafnium dioxide (HfO₂), aluminum nitride (AlN), titanium oxide (TiO₂), nickel oxide (Ni₂O₃), or hexagonal boron nitride (α-BN), but is not limited thereto. The suitable material may be selected based on process or product type. Preferably, the passivation layer 3 is made of aluminum oxide. Accumulated charge of the semiconductor transistor can be further reduced because the aluminum oxide causes a passivation effect on free Cu on a surface of the laminated copper oxide layer 2, thereby lowering the off-state current. This allows the passivation layer 3 made of Al₂O₃ to apparently enhance the performance and stability of the semiconductor transistor and component therein, especially the low current loss. The passivation layer 3 may have a thickness less than 20 nm.

In one embodiment, the source/drain layer 4 is disposed on the passivation layer 3. The source/drain layer 4 comprises a source electrode 41 and a drain electrode 42. Preferably, the source electrode 41 electrically connects the laminated copper oxide layer 2 through the source opening 31, and the drain electrode 42 electrically connects the laminated copper oxide layer 2 through the drain opening 32. The source electrode 41 and the drain electrode 42 may be made of nickel, gold, copper, aluminum, or titanium.

In one embodiment of the present invention, the semiconductor transistor has a leakage current less than 10 pA/μm.

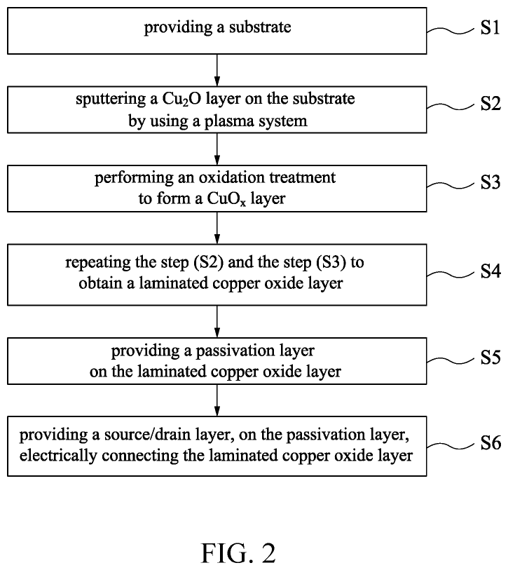

Referring to FIG. 2, another embodiment of the present invention provides a method of manufacturing a semiconductor transistor, comprising steps of (S1) providing a substrate; (S2) sputtering a Cu₂O layer on the substrate by using a plasma system; (S3) performing an oxidation treatment to form a CuOₓ layer; (S4) repeating the step (S2) and the step (S3) to obtain a laminated copper oxide layer; (S5) providing a passivation layer on the laminated copper oxide layer; and (S6) providing a source/drain layer, on the passivation layer, electrically connecting the laminated copper oxide layer.

The implementation details and principles of each of the above steps are described in detail below.

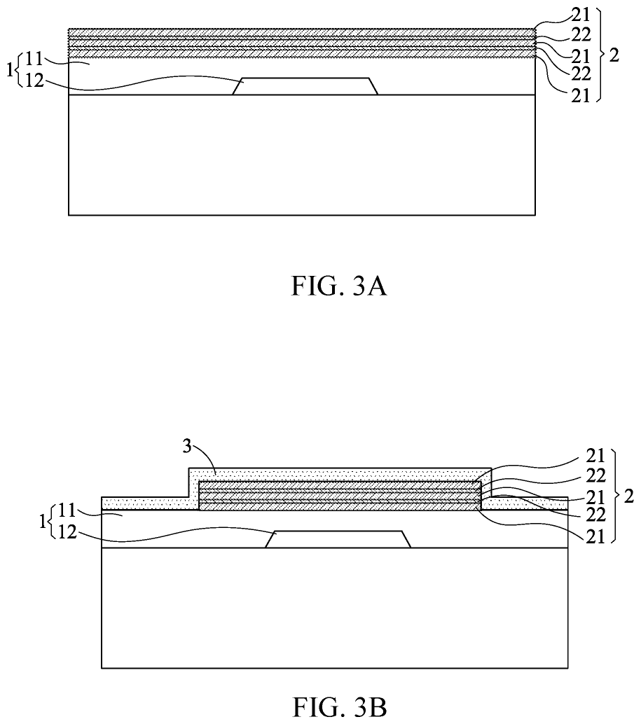

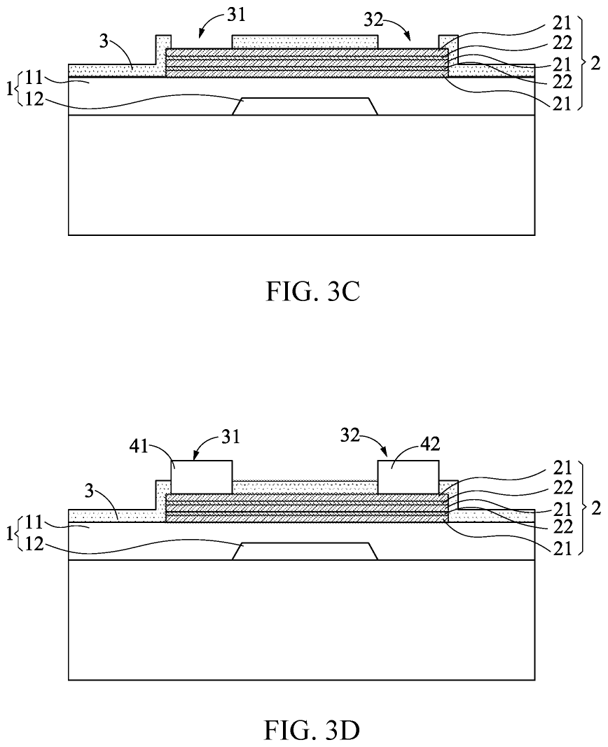

Referring to FIG. 2 and FIG. 3A, a method of manufacturing a semiconductor transistor according to one embodiment of the present invention is firstly a step of (S1) providing a substrate 1. In this step, the substrate 1 comprises a gate electrode 12 and a dielectric layer 11. The dielectric layer 11 may comprise silicon dioxide, aluminum oxide, silicon nitride, hafnium dioxide, aluminum nitride, titanium oxide, nickel oxide, and/or hexagonal boron nitride. The dielectric layer 11 may have a thickness of 100 nm, e.g. 20 nm, 50 nm, 80 nm, 100 nm, or 150 nm. The substrate 1 may be made of any material used for manufacturing a transistor. The material of the substrate 1 may be selected based on the implementation requirements. For example, the material of the substrate 1 may be silicon wafers, P++ silicon wafers, n++ silicon wafers, or metals. In mass production, the substrate 1 may also comprise a gate electrode array formed by a plurality of gate electrodes 12.

Next, referring to FIG. 2 and FIG. 3A, a method of manufacturing a semiconductor transistor according to one embodiment of the present invention is a step of (S2) sputtering a Cu₂O layer 21 on the substrate 1 by using a plasma system. In this step, the plasma system (not shown) provides an oxygen plasma flow for sputtering. The oxygen plasma flow contains argon and oxygen. The ratio of argon to oxygen, the flow rate of the oxygen plasma flow, and the pressure in the plasma system may be controlled within a desired range by the plasma system, so as to precisely control the thickness of the Cu₂O layer 21.

Next, referring to FIG. 2 and FIG. 3A, a method of manufacturing a semiconductor transistor according to one embodiment of the present invention is a step of (S3) performing an oxidation treatment to form a CuOₓ layer 22. In this step, the oxidation treatment is for the Cu₂O layer 21 formed in the step (S2). Preferably, the oxidation treatment is performed at a temperature of 20 °C to 30 °C, such as room temperature, 20, 25, or 30 °C, for 9.5-10.5 minutes, such as 9.5, 10, or 10.5 minutes.

Preferably, the oxidation treatment is performed in the plasma system when the oxygen plasma flow is stopped from being injected into the plasma system. Preferably, the Cu₂O layer 21 is placed within the plasma system for performing the oxidation treatment. In this step, the high-energy oxygen plasma particles of the plasma system enable precise control of the thickness of the Cu₂O layer 21 and the CuOx layer 22. The cyclic switching of the oxygen plasma flow for controlling the oxygen content within the plasma system and the duration of the oxidation treatment step enable effective control of the oxidation state and crystal quality of the Cu₂O layer 21 and the CuOx layer 22, thereby reducing oxygen vacancies and improving film uniformity and density.

Next, referring to FIG. 2 and FIG. 3A, a method of manufacturing a semiconductor transistor according to one embodiment of the present invention is a step of (S4) repeating the step (S2) and the step (S3) to obtain a laminated copper oxide layer 2. In one embodiment of the present invention, the number of times of repeating the step (S2) is different from or the same as the number of times of repeating the step (S3). For example, the step (S2) may be repeated 3 times and the step (S3) may be repeated 2 times to form 3 layers of the Cu₂O layer 21 with one CuOₓ layer 22 between one Cu₂O layer 21 and another Cu₂O layer 21. Alternatively, the step (S2) is repeated 2 times and the step (S3) is repeated 2 times to form 2 layers of the Cu₂O layer 21 with one CuOₓ layer 22 on each of the 2 layers of the Cu₂O layer 21. In one embodiment of the present invention, the laminated copper oxide layer 2 has a thickness ranging from 9.6 to 14.4 nm, such as 9.6 nm, 10 nm, 11.2 nm, 12 nm, 13 nm, or 14 nm, but is not limited thereto. It can also be any thickness between 9.6 and 14.4 nm. As described above, the plasma system can be used for controlling the oxygen content in the plasma system by the cyclic switching of the oxygen plasma flow, and the duration of repeating the sputtering of the step (S2) and the oxidation treatment of the step (S3), so as to effectively control the oxidation state and crystal quality of the Cu₂O layer 21 and the CuOₓ layer 22, thereby reducing oxygen vacancies and improving film uniformity and density.

In one embodiment of the present invention, after the step (S4), the laminated copper oxide layer 2 may be patterned, for example, by plasma etching, chemical etching, lift-off, or laser etching.

Next, referring to FIG. 2 and FIGS. 3B-3C, a method of manufacturing a semiconductor transistor according to one embodiment of the present invention is a step of (S5) providing a passivation layer 3 on the laminated copper oxide layer 2. As shown in FIG. 3C, in this step, the passivation layer 3 has a source opening 31 and a drain opening 32. The source opening 31 and the drain opening 32 may be formed by patterning method which is used in general semiconductor processes, such as etching, laser engraving, plasma etching, chemical etching, or lift-off.

In one embodiment of the present invention, after the step (S5), the method further comprises a step (S51) of annealing in a vacuum at a temperature of 300 °C-350 °C for 10-15 minutes.

Next, referring to FIG. 2 and FIG. 3D, a method of manufacturing a semiconductor transistor according to one embodiment of the present invention is a step of (S6) providing a source/drain layer 4, on the passivation layer 3, electrically connecting the laminated copper oxide layer 2. In this step, the source/drain layer 4 comprises a source electrode 41 and a drain electrode 42 and they may be electrically connected to the laminated copper oxide layer 2 via the source opening 31 and the drain opening 32, respectively. This step can be performed using the general semiconductor source/drain layer generation method, which will not be elaborated upon here.

In order to make the semiconductor transistor of the present invention and the method of manufacturing the semiconductor transistor more explicit and easier to understand, while verifying the electrical performance of the semiconductor transistor, please refer to the following practical operation process and examples. However, the examples below are not intended to limit the specific structure of the semiconductor transistor of the present invention or the individual steps included in the method of manufacturing the same.

### Example 1: Manufacturing a Semiconductor Transistor

A p-type Cu₂O thin film is deposited on a P++ silicon substrate with a dielectric layer by a DC plasma sputtering process under controlled power and gas ratio conditions. The process gases include argon and oxygen, with a gas ratio (argon to oxygen) between 20:1 and 30:1, and the copper oxide film is grown at room temperature under vacuum and controlled pressure. After completing the Cu₂O film deposition, an oxidation treatment is continuously performed in the same chamber to convert the surface of the copper oxide film into a CuOₓ layer. This deposition and oxidation treatment are repeated multiple times to construct a multilayer p-type copper oxide structure. Subsequently, a thermal treatment step is conducted by rapid thermal annealing in a vacuum environment at approximately 300 °C-350 °C to enhance film properties. Wet etching may then be performed to form isolation regions, followed by deposition of a high-k dielectric material on the laminated copper oxide layer as a passivation layer. For example, a plasma atomic-level deposition equipment may be used to deposit the passivation layer, such as aluminum oxide (Al₂O₃) with a thickness less than 20 nm. Finally, openings for the source electrode and drain electrode are formed on the passivation layer, and metal electrodes are fabricated through metal deposition and patterning processes (including electron-beam evaporation of nickel and lift-off patterning methods). The source and drain electrodes are electrically connected to the underlying copper oxide layer.

### Example 2: Performing Electrical Testing

A semiconductor parameter analyzer, such as the Keysight B1500A, can be used with a probe platform controlled by a microprobe. A scanning voltage, ranging from −60V to 40V, is applied to the device's gate electrode via the probe platform's metal stage. Simultaneously, the source electrode is grounded, and a fixed negative bias (e.g., −10V) is applied to the drain electrode. The changes of the current in the drain electrode under different gate electrode bias voltages are measured, and the conversion characteristic curve I_{d}-V_{g} is obtained. Furthermore, this measurement method can also be applied to devices with different channel lengths to analyze the impact of channel effects on device characteristics.

TABLE 1

| Channel length (microns) | 5 | 10 | 15 | 20 | 25 |
|---|---|---|---|---|---|
| Iₒₙ/I_{off} | 68 | 69 | 75 | 80 | 140 |

As shown in Table 1, the semiconductor transistor of the present invention achieves an on/off ratio greater than 140, which is superior to the current on/off ratio of conventional p-type oxide thin-film transistors (10-10², Id_{on,max} can reach 10⁻⁶A under annealing at 300 °C). Therefore, the electrical performance of thin-film transistors is improved. Furthermore, the method of manufacturing the semiconductor transistor as provided in the present invention does not use any doping process. The method only utilizes ionized gas (plasma) for sputtering and oxidation of the cuprous oxide layer. This effectively controls the film thickness, generates a highly uniform copper oxide film, and improves film quality. Simultaneously, annealing can be performed at temperatures below 400 °C, and therefore the probability of damage to electronic components and substrates caused by high-temperature processing is reduced, thereby improving process yield.

### Example 3: Verifying Improvement of Aluminum Oxide Passivation Layer

Referring to the inventor's research in 2024 (H. C. Chen et al., J. Vac. Sci. Technol. 2024, A 42, 053412), a single p-type Cu₂O film was deposited on a P++ silicon substrate with a dielectric layer by using a DC plasma sputtering process under controlled power and gas ratio conditions. The I_{d}-V_{g} conversion characteristic curve revealed a current on/off ratio of only about 10. By using plasma atomic-level deposition of aluminum oxide (Al₂O₃) in a single p-type Cu₂O thin film, an on/off ratio of 106 (Id_{on,max} 10⁻⁷ A) can be achieved, demonstrating that aluminum oxide can effectively improve the on/off ratio.

### Comparison 1:

Referring to the study in 2020 (J. H. Bae et al., ACS Appl. Mater. Interfaces, 2020, 34, 38350), a radio frequency magnetron sputtering (RFMS) technology is used for doping Ga to form a Ga:Cu₂O thin film. This method helps to reduce the number of oxygen vacancies and improve the low current on/off ratio of p-type Cu₂O transistors. The current on/off ratio of the fabricated device is 2.74×10². However, the above method requires subsequent processing at a high temperature of about 800 °C, which cannot meet the requirements of a temperature below 400 °C in the next stage of BEOL process, and the dopant concentration needs to be strictly controlled, resulting in poor process stability.

The present application has been described by the above related embodiments, but the above embodiments are merely examples for implementing the present application. It must be noted that the disclosed embodiments do not limit the scope of the present application. Rather, modifications and equivalent arrangements included in the spirit and scope of the claims are intended to be included within the scope of the present application.

What is claimed is:

1. A semiconductor transistor, comprising:
a substrate comprising a gate electrode and a dielectric layer, wherein the dielectric layer is disposed on the gate electrode;
a laminated copper oxide layer disposed on the substrate;
a passivation layer covering the laminated copper oxide layer, wherein the passivation layer has a source opening and a drain opening; and
a source/drain layer disposed on the passivation layer, wherein the source/drain layer comprises a source electrode and a drain electrode, and wherein the source electrode and the drain electrode electrically connect the laminated copper oxide layer through the source opening and the drain opening, respectively;
wherein the laminated copper oxide layer comprises at least one Cu₂O layer and at least one CuOₓ layer, one of the at least one Cu₂O layer and one of the at least one CuOₓ layer are stacked with each other, and x is greater than or equal to 1.

2. The semiconductor transistor according to claim 1, wherein the dielectric layer comprises silicon dioxide.

3. The semiconductor transistor according to claim 1, wherein the passivation layer comprises aluminum oxide.

4. The semiconductor transistor according to claim 1, wherein the laminated copper oxide layer has a thickness ranging from 9.6 nm to 14.4 nm.

5. The semiconductor transistor according to claim 1, wherein the semiconductor transistor has a leakage current less than 10 pA/μm.

6. A method of manufacturing a semiconductor transistor, comprising steps of:
(S1) providing a substrate comprising a gate electrode and a dielectric layer disposed on the gate electrode;
(S2) sputtering a Cu₂O layer on the substrate by using a plasma system;
(S3) performing an oxidation treatment to form a CuOₓ layer on a surface of the Cu₂O layer, wherein x is greater than or equal to 1;
(S4) repeating the step (S2) and the step (S3) to obtain a laminated copper oxide layer;
(S5) providing a passivation layer on the laminated copper oxide layer, wherein the passivation layer has a source opening and a drain opening; and
(S6) providing a source/drain layer on the passivation layer, wherein the source/drain layer comprises a source electrode and a drain electrode, the source electrode and the drain electrode electrically connect the laminated copper oxide layer through the source opening and the drain opening, respectively.

7. The method according to claim 6, wherein in the step (S1), the dielectric layer comprises silicon dioxide, and the dielectric layer has a thickness ranging from 20 nm to 150 nm.

8. The method according to claim 6, wherein in the step (S2), the plasma system provides an oxygen plasma flow for sputtering, and in the step (S3), the oxidation treatment is performed in the plasma system when the oxygen plasma flow is stopped from being injected into the plasma system.

9. The method according to claim 6, wherein the oxidation treatment is performed at a temperature of 20-30 °C for 9.5-10.5 minutes.

10. The method according to claim 6, wherein the laminated copper oxide layer has a thickness ranging from 9.6 nm to 14.4 nm.

11. The method according to claim 6, wherein in the step (S4), the number of times of repeating the step (S2) is different from or the same as the number of times of repeating the step (S3).

12. The method according to claim 6, further comprising a step after the step (S5):(S51) annealing in a vacuum at a temperature of 300 °C-350 °C for 10-15 minutes.
